(19) United States
(12) Patent Application Publication
(10) Pub. No.: US 2024/0268120 A1
(43) Pub. Date: Aug. 8, 2024

(54) SEMICONDUCTOR STRUCTURE AND METHOD FOR MANUFACTURING THE SAME

(71) Applicant: MACRONIX INTERNATIONAL CO., LTD., Hsinchu (TW)

(72) Inventors: Yung-Hsiang CHEN, Taipei City (TW); Tao-Cheng LU, Hsinchu City (TW); Yao-Wen CHANG, Zhubei City (TW)

(21) Appl. No.: 18/165,958

(22) Filed: Feb. 8, 2023

(51) Int. Cl. H10B 43/35; H01L 23/528; H10B 41/20; H10B 41/35; H10B 41/40; H10B 43/20; H10B 43/40

(52) U.S. Cl. CPC H10B 43/35; H01L 23/5283; H10B 41/20; H10B 41/35; H10B 41/40; H10B 43/20; H10B 43/40

(57) ABSTRACT

A semiconductor structure is provided. The semiconductor structure includes a first substrate, a first circuit layer, a memory array structure, a bonding layer, a second circuit layer, and a second substrate. The first circuit layer is disposed on the first substrate. The memory array structure is disposed on the first circuit layer. The bonding layer is disposed on the memory array structure. The second circuit layer is disposed on the bonding layer. The second substrate is disposed on the second circuit layer.

### TECHNICAL FIELD

This disclosure relates to a semiconductor structure and a method for manufacturing the same. More particularly, this disclosure relates to a semiconductor structure comprising a memory array structure and a circuit layer and a method for manufacturing the same.

### BACKGROUND

In a conventional semiconductor device having a memory array, circuit devices for controlling the memory array are disposed in a circuit area near the array area. As the number of memory cells in a semiconductor device increases, more circuit devices are required for controlling a memory array. One solution is to form a circuit layer on the whole substrate followed with a memory array structure formed thereon. Another solution that can provide even more circuit devices is to provide another substrate for the formation of additional circuit devices and connects it to the original semiconductor structure with through silicon vias. However, in both solutions, the circuit devices under the memory array structure may be deteriorated by the process for manufacturing the memory array, and thus performance of the circuit devices is low. In some cases, even the memory array may be deteriorated.

### SUMMARY

In this disclosure, a semiconductor structure having more devices with high performance for controlling the memory array and a method for manufacturing the same are provided.

A semiconductor structure according to embodiments comprises a first substrate, a first circuit layer, a memory array structure, a bonding layer, a second circuit layer, and a second substrate. The first circuit layer is disposed on the first substrate. The memory array structure is disposed on the first circuit layer. The bonding layer is disposed on the memory array structure. The second circuit layer is disposed on the bonding layer. The second substrate is disposed on the second circuit layer.

A method for manufacturing a semiconductor structure according to embodiments comprises following steps. A first structure is provided. The first structure comprises a first substrate, a first circuit layer, and a memory array structure, wherein the first circuit layer is formed on the first substrate, and the memory array structure is formed on the first circuit layer. A second structure is provided. The second structure comprises a second substrate and a second circuit layer, wherein the second circuit layer is formed on the second substrate. The second structure is bonded to the first structure, wherein the second circuit layer is toward the first structure.

### BRIEF DESCRIPTION OF THE DRAWINGS

FIGS. 1A-1B illustrate an exemplary semiconductor structure.

FIG. 2 illustrates another exemplary semiconductor structure.

FIGS. 3A-3D illustrate various stages of an exemplary method for manufacturing a semiconductor structure.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

Various embodiments will be described more fully hereinafter with reference to accompanying drawings. The description and the drawings are provided for illustrative only, and not intended to result in a limitation. For clarity, the elements may not be drawn to scale. In addition, some elements and/or reference numerals may be omitted from some drawings. It is contemplated that the elements and features of one embodiment can be beneficially incorporated in another embodiment without further recitation.

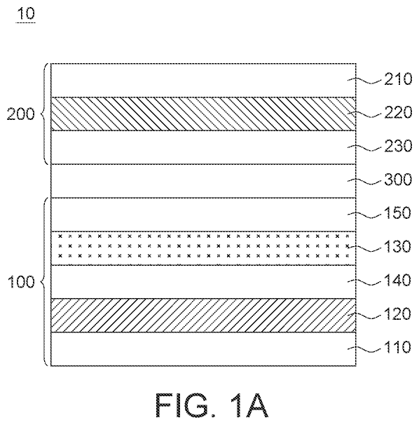

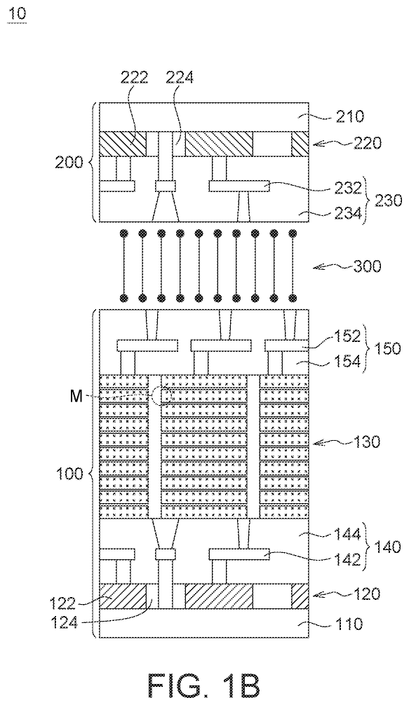

Referring to FIGS. 1A-1B, an exemplary semiconductor structure 10 of the disclosure is shown, wherein FIG. 1A shows a basic structure, and FIG. 1B shows more exemplary details of the structure.

The semiconductor structure 10 comprises a first substrate 110, a first circuit layer 120, a memory array structure 130, a bonding layer 300, a second circuit layer 220, and a second substrate 210. The first circuit layer 120 is disposed on the first substrate 110. The memory array structure 130 is disposed on the first circuit layer 120. The bonding layer 300 is disposed on the memory array structure 130. The second circuit layer 220 is disposed on the bonding layer 300. The second substrate 210 is disposed on the second circuit layer 220.

More specifically, the first substrate 110 and the second substrate 210 can be individually comprise Si or the like. However, the disclosure is not limited thereto.

The first circuit layer 120 and the second circuit layer 220 are configured for controlling the memory array structure 130. For example, various CMOS devices 122/222 can be used in the first circuit layer 120 and the second circuit layer 220, which are separated from each other by isolation structures 124/224.

The first circuit layer 120 can comprise circuit devices that can tolerate thermal budget of the array process, such as high voltage devices and long gate length devices. For example, the first circuit layer 120 can comprise at least one of a device applicable with a voltage equal to or higher than 20 V (such as a device used for transporting a writing voltage) or a device having a gate length equal to or higher than 100 nm.

The second circuit layer 220 can comprise various high performance devices, which typically cannot tolerate heavy thermal budget of the array process, such as input/output devices and short gate length devices. In addition, advanced processes for CMOS can be applied to the second circuit layer 220, such as a finFET process, a SiGe process, or a high-k metal gate process. As such, the second circuit layer 220 can comprise at least one of an input/output device, a device having a gate length lower than or equal to 100 nm, a FinFET, a device comprising a SiGe layer, or a device comprising a metal gate.

The memory array structure 130 can have a 3D NAND array structure, a 2D NAND array structure, a 3D NOR array structure, or a 2D NOR array structure. The memory array structure 130 can comprise as floating gate memory cells or charge trapping memory cells M. However, the disclosure is not limited thereto.

The semiconductor structure 10 can further comprise a first connection layer 140. The first connection layer 140 is disposed on the first circuit layer 120. The memory array structure 130 is disposed on the first connection layer 140. The first connection layer 140 can be used for the connection, either mechanical or electrical, between the first circuit layer 120 and the memory array structure 130. The semiconductor structure 10 can further comprise a second connection layer 150. The second connection layer 150 is disposed on the memory array structure 130. The bonding layer 300 is disposed on the second connection layer 150. The second connection layer 150 can be used for the connection, either mechanical or electrical, of the memory array structure 130. The semiconductor structure 10 can further comprise a third connection layer 230. The third connection layer 230 is disposed on the bonding layer 300. The second circuit layer 220 is disposed on the third connection layer 230. The third connection layer 230 can be used for the connection, either mechanical or electrical, of the second circuit layer 220.

According to some embodiments, each of the first connection layer 140, the second connection layer 150, and the third connection layer 230 can comprise a dielectric layer and a plurality of conductors disposed in the dielectric layer. Specifically, the first connection layer 140 can comprise conductors 142 and a dielectric layer 144. The conductors 142 can comprise wires and vias, but not limited thereto. The conductors 142 can comprise W. The second connection layer 150 can comprise conductors 152 and a dielectric layer 154. The conductors 152 can comprise wires and vias, but not limited thereto. The conductors 152 can comprise W. The third connection layer 230 can comprise conductors 232 and a dielectric layer 234. The conductors 232 can comprise wires and vias, but not limited thereto. The conductors 232 of the third connection layer 230 can comprise Cu, which has lower metal resistance but is sensitive to heavy thermal budget.

It can be understood that the semiconductor structure 10 can be seen as a first structure 100 and a second structure 200 bonded together through the bonding layer 300, wherein the first structure 100 comprises the first substrate 110, the first circuit layer 120, the first connection layer 140, the memory array structure 130, and the second connection layer 150, and the second structure 200 comprises the second substrate 210, the second circuit layer 220, and the third connection layer 230. The bonding layer 300 can comprise metal. However, the disclosure is not limited thereto. Any suitable bonding means can be applied to the bonding layer 300.

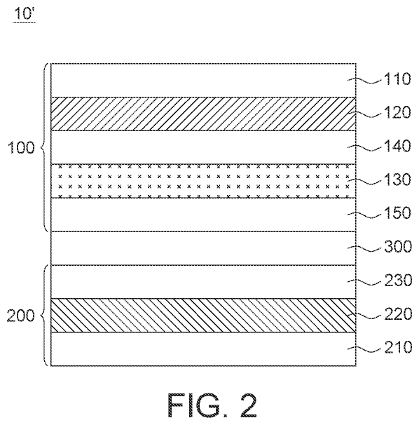

In this disclosure, various spatial terms, such as “on,” “under,” “side,” and the like, are used in distinguishing one element from another element in a relative manner. However, it should be understood that the elements may be oriented in different manners. For example, another exemplary semiconductor structure 10′ as shown in FIG. 2 is substantially a vertical flipping of the semiconductor structure 10.

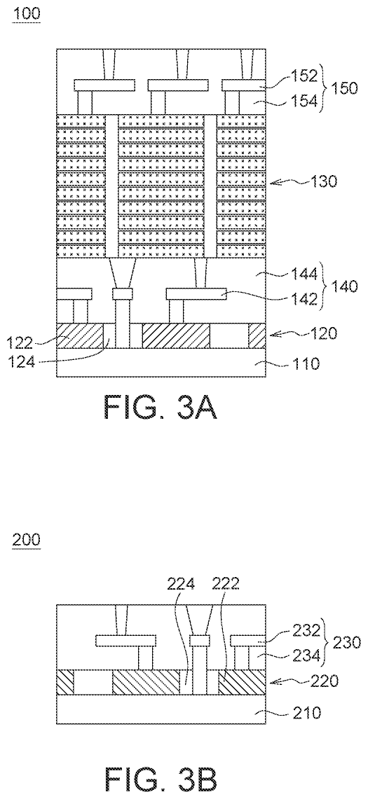

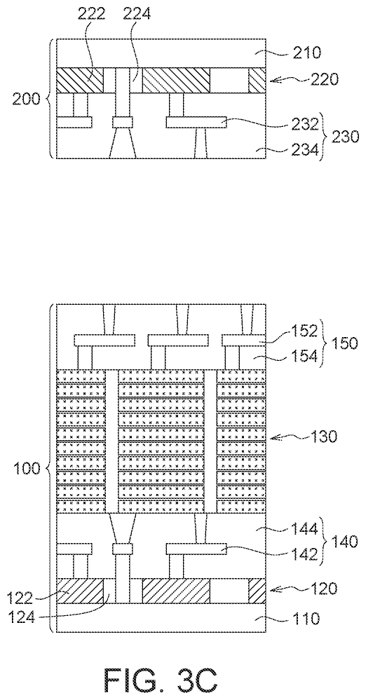

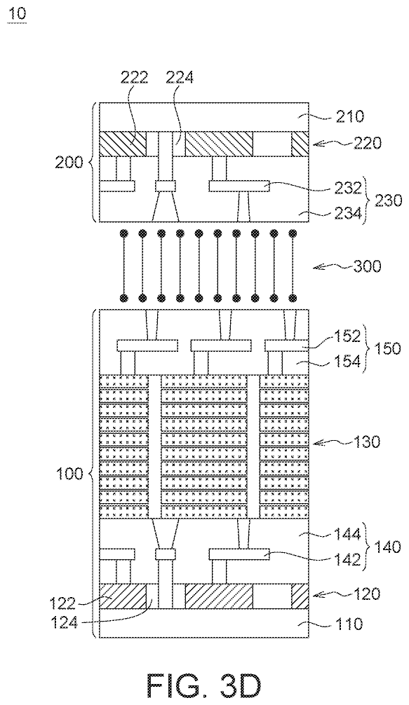

Referring to FIGS. 3A-3D, an exemplary method of the disclosure for manufacturing the semiconductor structure is shown.

As shown in FIG. 3A, a first structure 100 is provided. The first structure 100 comprises a first substrate 110, a first circuit layer 120, and a memory array structure 130. The first circuit layer 120 is formed on the first substrate 110. The memory array structure 130 is formed on the first circuit layer 120. The first structure 100 can further comprise a first connection layer 140 and a second connection layer 150. In such cases, the first connection layer 140 is formed on the first circuit layer 120. The memory array structure 130 is formed on the first connection layer 140. The second connection layer 150 is formed on the memory array structure 130.

Specifically, the first circuit layer 120 is configured for controlling the memory array structure 130. The first circuit layer 120 can comprise circuit devices that can tolerate thermal budget of the array process. For example, the first circuit layer 120 can comprise at least one of a device applicable with a voltage equal to or higher than 20 V or a device having a gate length equal to or higher than 100 nm.

The memory array structure 130 can have a 3D NAND array structure, a 2D NAND array structure, a 3D NOR array structure, or a 2D NOR array structure. The memory array structure 130 can comprise floating gate memory cells or charge trapping memory cells M.

The first connection layer 140 can be used for the connection between the first circuit layer 120 and the memory array structure 130. The first connection layer 140 can comprise a dielectric layer 144 and a plurality of conductors 142 formed in the dielectric layer 144.

The second connection layer 150 can be used for the connection of the memory array structure 130. The second connection layer 150 can comprise a dielectric layer 154 and a plurality of conductors 152 formed in the dielectric layer 154.

As shown in FIG. 3B, a second structure 200 is provided. The second structure 200 comprises a second substrate 210 and a second circuit layer 220. The second circuit layer 220 is formed on the second substrate 210. The second structure 200 can further comprise a third connection layer 230. The third connection layer 230 is formed on the second circuit layer 220. The second structure 200 does not comprise a memory array structure.

Specifically, the second circuit layer 220 is also configured for controlling the memory array structure 130. Since the second structure 200 does not comprise a memory array structure, high performance devices and more advanced structure for CMOS, which are sensitive to heavy thermal budget, can be formed. For example, the second circuit layer 220 can comprise at least one of an input/output device, a device having a gate length lower than or equal to 100 nm, a FinFET, a device comprising a SiGe layer, or a device comprising a metal gate.

The third connection layer 230 can be used for the connection of the second circuit layer 220. The third connection layer 230 can comprise a dielectric layer 234 and a plurality of conductors 232 formed in the dielectric layer 234. Since the second structure 200 does not comprise a memory array structure, the conductors 232 of the third connection layer 230 can be formed of a Cu metal process, which is sensitive to heavy thermal budget but can provide lower metal resistance.

As shown in FIG. 3C, before bonding the second structure 200 to the first structure 100, the second structure 200 can be flipped such that the second circuit layer 220 is toward the first structure 100. In other words, the first structure 100 and the second structure 200 face to each other in a manner that a surface of the first substrate 110 having the first circuit layer 120 and the memory array structure 130 thereon faces a surface of the second substrate 210 having the second circuit layer 220 thereon.

Then, as shown in FIG. 3D, the second structure 200 is bonded to the first structure 100 in such relative direction, wherein the second circuit layer 220 is toward the first structure 100. In some embodiments, a bonding layer 300 comprising metal can be formed.

According to this disclosure, additional high performance circuit devices are provided on another substrate and then bonded to the structure having a memory array structure and the circuit devices that are less sensitive to the thermal budget of the array process. As such, a semiconductor structure having more devices with high performance for controlling the memory array can be manufactured by a simple method. In addition, high performance memory array and high performance circuit devices can be provided at the same time.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A semiconductor structure, comprising:
a first substrate;
a first circuit layer disposed on the first substrate;
a memory array structure disposed on the first circuit layer;
a bonding layer disposed on the memory array structure;
a second circuit layer disposed on the bonding layer; and
a second substrate disposed on the second circuit layer.

2. The semiconductor structure according to claim 1, wherein the memory array structure has a 3D NAND array structure, a 2D NAND array structure, a 3D NOR array structure, or a 2D NOR array structure.

3. The semiconductor structure according to claim 1, wherein the memory array structure comprises floating gate memory cells or charge trapping memory cells.

4. The semiconductor structure according to claim 1, wherein the first circuit layer and the second circuit layer are configured for controlling the memory array structure.

5. The semiconductor structure according to claim 1, wherein the first circuit layer comprises at least one of a device applicable with a voltage equal to or higher than 20 V or a device having a gate length equal to or higher than 100 nm.

6. The semiconductor structure according to claim 1, wherein the second circuit layer comprises at least one of an input/output device, a device having a gate length lower than or equal to 100 nm, a FinFET, a device comprising a SiGe layer, or a device comprising a metal gate.

7. The semiconductor structure according to claim 1, further comprising:
a first connection layer disposed on the first circuit layer, wherein the memory array structure is disposed on the first connection layer;
a second connection layer disposed on the memory array structure, wherein the bonding layer is disposed on the second connection layer; and
a third connection layer disposed on the bonding layer, wherein the second circuit layer is disposed on the third connection layer.

8. The semiconductor structure according to claim 7, wherein each of the first connection layer, the second connection layer, and the third connection layer comprises a dielectric layer and a plurality of conductors disposed in the dielectric layer.

9. The semiconductor structure according to claim 8, wherein the conductors of the third connection layer comprise Cu.

10. The semiconductor structure according to claim 1, wherein the bonding layer comprises metal.

11. A method for manufacturing a semiconductor structure, comprising:
providing a first structure comprising a first substrate, a first circuit layer, and a memory array structure, wherein the first circuit layer is formed on the first substrate, and the memory array structure is formed on the first circuit layer;
providing a second structure comprising a second substrate and a second circuit layer, wherein the second circuit layer is formed on the second substrate; and
bonding the second structure to the first structure, wherein the second circuit layer is toward the first structure.

12. The method according to claim 11, further comprising:
before bonding the second structure to the first structure, flipping the second structure such that the second circuit layer is toward the first structure.

13. The method according to claim 11, wherein in providing the first structure, the memory array structure has a 3D NAND array structure, a 2D NAND array structure, a 3D NOR array structure, or a 2D NOR array structure, and/or the memory array structure comprises floating gate memory cells or charge trapping memory cells.

14. The method according to claim 11, wherein the first circuit layer and the second circuit layer are configured for controlling the memory array structure.

15. The method according to claim 11, wherein in providing the first structure, the first circuit layer comprises at least one of a device applicable with a voltage equal to or higher than 20 V or a device having a gate length equal to or higher than 100 nm.

16. The method according to claim 11, wherein in providing the second structure, the second circuit layer comprises at least one of an input/output device, a device having a gate length lower than or equal to 100 nm, a FinFET, a device comprising a SiGe layer, or a device comprising a metal gate.

17. The method according to claim 11, wherein in providing the first structure, the first structure further comprises a first connection layer and a second connection layer, the first connection layer is formed on the first circuit layer, the memory array structure is formed on the first connection layer, and the second connection layer is formed on the memory array structure, and wherein in providing the second structure, the second structure further comprises a third connection layer, and the third connection layer is formed on the second circuit layer.

18. The method according to claim 17, wherein each of the first connection layer, the second connection layer, and the third connection layer comprises a dielectric layer and a plurality of conductors formed in the dielectric layer.

19. The method according to claim 18, wherein the conductors of the third connection layer is formed of a Cu metal process.

20. The method according to claim 11, wherein in bonding the second structure to the first structure, a bonding layer comprising metal is formed.
